(19) United States
(12) Patent Application Publication
(10) Pub. No.: US 2025/0048679 A1
(43) Pub. Date: Feb. 6, 2025

(54) ELECTRONIC DEVICE AND MANUFACTURING METHOD THEREOF

(71) Applicant: InnoLux Corporation, Miao-Li County (TW)

(72) Inventors: Chandra LIUS, Miao-Li County (TW); Jhe-Ciou JHU, Miao-Li County (TW); Chung-Wen YEN, Miao-Li County (TW); Nai-Fang HSU, Miao-Li County (TW); Ai-Ling KUO, Miao-Li County (TW)

(21) Appl. No.: 18/763,109

(22) Filed: Jul. 3, 2024

(30) Foreign Application Priority Data
Aug. 1, 2023 (CN) 202310960419.0

(51) Int. Cl. H01L 29/786; H01L 21/02; H01L 21/425; H01L 29/66

(52) U.S. Cl. CPC H01L 29/7869; H01L 21/02565; H01L 21/425; H01L 29/66969; H01L 29/78603; H01L 29/78633; H01L 29/78696

(57) ABSTRACT

An electronic device and a manufacturing method thereof are provided. The electronic device includes a substrate, a buffer layer, an oxide semiconductor layer, and a gate electrode. The buffer layer is disposed on the substrate. The oxide semiconductor layer is disposed on the buffer layer and has a first part and a second part adjacent to the first part. The gate electrode is overlapped with the first part. A part of the buffer layer is overlapped with the second part of the oxide semiconductor layer, The part of the buffer layer has a first portion and a second portion disposed on the first portion. The concentration of boron in the first portion is greater than the concentration of boron in the second portion.

### CROSS REFERENCE TO RELATED APPLICATIONS

This application claims priority of China Patent Application No. CN 202310960419.0, filed on Aug. 1, 2023, the entirety of which is incorporated by reference herein.

### TECHNICAL FIELD

Some embodiments of the present disclosure relate to an electronic device and a manufacturing method thereof, and, in particular, to an electronic device including a buffer layer and a manufacturing method of the electronic device.

### BACKGROUND

Electronic products that include chips, such as displays, smartphones, tablets, notebook computers, and televisions, have become indispensable necessities in modern society. With the booming development of these types of electronic products, consumers have high expectations on their quality, functionality, or price of these electronic products.

Electronic products often include transistors to perform operations. However, due to the need for doping in the process of manufacturing transistors, unnecessary diffusion of dopants may occur, which can reduce the stability of the transistors. Therefore, these electronic products do not meet consumer demand in all respects, and there are still some problems with electronic products that need to be solved. The development of improved electronic devices and manufacturing methods thereof remains one of the current goals of the industry.

### SUMMARY

In some embodiments, an electronic device is provided. The electronic device includes a substrate, a buffer layer, an oxide semiconductor layer, and a gate electrode. The buffer layer is disposed on the substrate. The oxide semiconductor layer is disposed on the buffer layer and has a first part and a second part adjacent to the first part. The gate electrode is overlapped with the first part. A part of the buffer layer is overlapped with the second part of the oxide semiconductor layer, the part of the buffer layer has a first portion and a second portion disposed on the first portion, and a concentration of boron in the first portion is greater than a concentration of boron in the second portion.

In some embodiments, a method of manufacturing an electronic device is provided. The manufacturing method includes providing a substrate. A buffer layer is formed on the substrate. An oxide semiconductor layer is formed on the buffer layer, the oxide semiconductor layer has a first part and a second part. A gate electrode is formed on the buffer layer, and the gate electrode is overlapped the first part. An ion implantation process is performed by boron on the oxide semiconductor layer. Wherein, a part of the buffer layer is overlapped with the second part of the oxide semiconductor layer, the part of the buffer layer has a first portion and a second portion disposed on the first portion, and after the ion implantation process, a concentration of boron in the first portion is greater than a concentration of boron in the second portion.

The electronic device and manufacturing method thereof of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 shows a schematic cross-sectional view of an electronic device according to some embodiments of the present disclosure.

FIG. 2 shows a schematic cross-sectional view of an electronic device according to some embodiments of the present disclosure.

FIG. 3 shows a schematic cross-sectional view of an electronic device according to some embodiments of the present disclosure.

FIGS. 4A to 4E respectively show schematic elemental analysis diagrams of an electronic device according to some embodiments of the present disclosure.

FIG. 5 shows a schematic elemental analysis diagram of an electronic device according to some embodiments of the present disclosure.

### DETAILED DESCRIPTION

Electronic device and manufacturing method thereof of various embodiments of the present disclosure will be described in detail below. It should be understood that the following description provides many different embodiments for implementing various aspects of some embodiments of the present disclosure. The specific components and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding components in order to clearly describe the present disclosure. However, the use of these similar or corresponding reference numerals is only for the purpose of simply and clearly description of some embodiments of the present disclosure, and does not imply any correlation between the different embodiments or structures discussed.

It should be understood that relative terms, such as “lower”, “bottom”, “higher”, or “top” may be used in various embodiments to describe the relative relationship of one component of the drawings to another component. It will be understood that if the device in the drawings were turned upside down, components described on the “lower” side would become components on the “upper” side. The embodiments of the present disclosure can be understood together with the drawings, and the drawings of the present disclosure are also regarded as a portion of the disclosure.

Furthermore, when it is mentioned that a first material layer is located “on” or “over” a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact.

In addition, it should be understood that ordinal numbers such as “first”, “second”, and the like used in the description and claims are used to modify components and are not intended to imply and represent the component(s) have any previous ordinal numbers, and do not represent the order of a certain component and another component, or the order of the manufacturing method, and the use of these ordinal numbers is only used to clearly distinguished an component with a certain name and another component with the same name. The claims and the specification may not use the same terms, for example, a first component in the specification may be a second component in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection can also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in the present disclosure to refer to specific components. A person of ordinary skills in the art should be understood that electronic device manufacturers may refer to the same component by different terms. The present disclosure does not intend to distinguish between components that have the same function but with different terms. In the following description and claims, terms such as “including”, “comprising”, and “having” are open-ended words, so they should be interpreted as meaning “including but not limited to . . . ”. Therefore, when the terms “including”, “comprising”, and/or “having” is used in the description of the present disclosure, it designates the presence of corresponding features, regions, steps, operations, and/or components, but does not exclude the presence of one or more corresponding features, regions, steps, operations, and/or components.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction D1 and the Z-axis direction is the second direction D2. In some embodiments, the schematic cross-sectional views described herein are schematic views of the XZ plane. In some embodiments, a normal direction of the substrate is the second direction D2.

It should be understood that, according to the embodiments of the present disclosure, relative setting relationship between components, a depth, a thickness, a width, or a height of each component, and a spacing or a distance between components may be measured by using an optical microscope (OM), a scanning electron microscope (SEM), a film thickness profiler (α-step), ellipsometer, or other suitable methods. According to some embodiments, a cross-sectional structure image including a component to be measured may be obtained by using the scanning electron microscope, and then the depth, the thickness, the width, or the height of the component, and the spacing or the distance between components may be measured.

It should be understood that according to embodiments of the present disclosure, time of flight secondary ion mass spectrometer (TOF-SIMS) or other suitable mass spectrometry methods may be used to quantitatively analyze and/or qualitative analysis of the elements in each component. According to some embodiments, a sample including an element to be measured may be obtained from an electronic device, and the elements in the sample may be analyzed. In some embodiments, the sample may be analyzed by using TOF-SIMS in negative ion mode, TOF-SIMS in positive ion mode, or a combination thereof. In some embodiments, the concentration of the sample that may be obtained depends on the accuracy of the analytical method used, and different analytical methods may have different minimum analyzable values. When the concentration of an element in the sample is less than the minimum analyzable value, it may only qualitatively analyze whether the element exists and describe the relative content relationship between the element and other elements, but it cannot quantitatively analyze the concentration of the element. In other words, the element may be substantially absent from the sample, that is, the concentration of the element is substantially equal to 0, or the element may be substantially included in the sample, that is, the concentration of the element is substantially greater than 0, but the concentration of the element is lower than the minimum analyzable value.

It should be understood that in the following, the unit of concentration “atoms/c.c.” represents the number of atoms included per cubic centimeter. In the following, when it is described that “the concentration of an element in the first component is greater than the concentration of the element in the second component”, it means that the concentration of the element measured at an arbitrary point in the first component is greater than the concentration of the element measured at an arbitrary point in the second component. For example, the concentration of the element at half the thickness of the first component is greater than the concentration of the element at half the thickness of the second component. For example, the maximum concentration value of the element in the first component is greater than the maximum concentration value of the element in the second component, but the present disclosure is not limited thereto. For example, the concentration of the element measured at a first point in the first component is greater than the concentration of the element measured at a second point in the second component, and the concentration of the element measured at a third point different from the first point in the first component may be smaller than or equal to the concentration of the element measured at the second point in the second component. In addition, when it is described that “the concentration of an element in the first component is greater than the concentration of the element in the second component”, it includes the case where the second component does not substantially include the element. In other words, the description includes the case where the concentration of the element in the first component is greater than the concentration of the element in the second component, and the concentration of the element in the second component is substantially zero.

In some embodiments, the electronic device of the present disclosure may include a display module, a back light module, an antenna module, a sensing module, or a titling module, but the present disclosure is not limited thereto. The electronic device may be a foldable or flexible electronic device. The display module may be a non-self-luminous display module or a self-luminous display module. The antenna module may be a liquid-crystal antenna module or a non-liquid-crystal antenna module. The sensing device may be a sensing module for sensing capacitance, light, heat, or ultrasonic waves, but the present disclosure is not limited thereto. The electronic elements may include passive elements and active elements, such as capacitors, resistors, inductors, diodes, transistors, and the like. The diodes may include light-emitting diodes or photodiodes. The light-emitting diodes may include, for example, organic light-emitting diodes (OLEDs), mini light-emitting diodes (mini LEDs), micro light-emitting diodes (micro LEDs), or quantum dot light-emitting diodes (quantum dot LED), but the present disclosure is not limited thereto. The titling module may be, for example, a display titling module or an antenna titling module, but the present disclosure is not limited thereto.

In addition, the shape of the electronic device may be rectangular, circular, polygonal, a shape with curved edges, or another suitable shape. The electronic device may have a peripheral system, such as a processing system, a driving system, a controlling system, a light source system, a shelf system, or the like to support the display module or the titling module.

It should be understood that, for clarity of explanation, some elements of the electronic device may be omitted in the drawings, and some elements are schematically illustrated. In some embodiments, additional elements may be added to the electronic device described below. In other embodiments, some elements of the electronic device described below may be replaced or omitted. It should be understood that, in some embodiments, additional operational steps may be provided before, during, and/or after the manufacturing method of an electronic device. In some embodiments, some of the described operational steps may be replaced or omitted, and the described order of some of the operational steps is interchangeable.

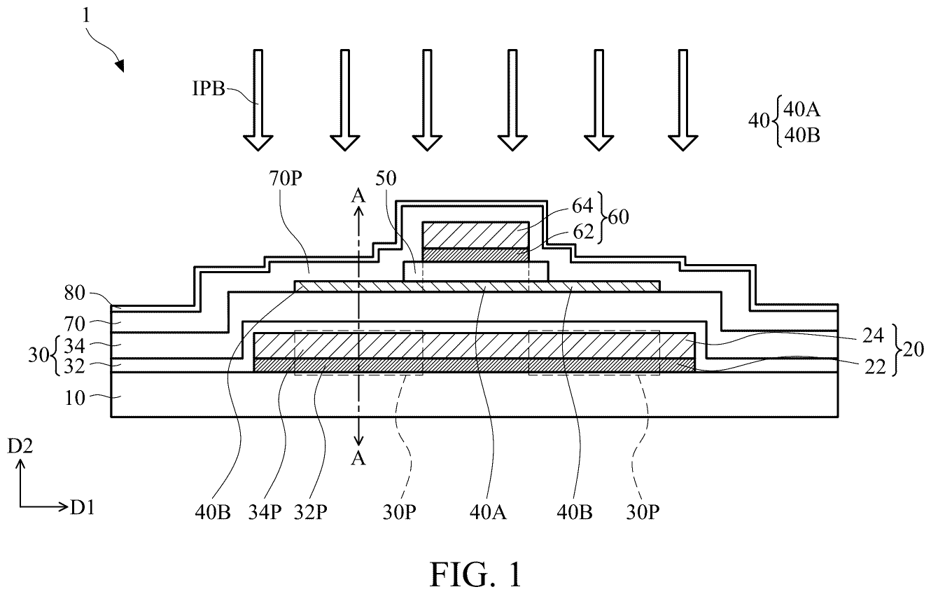

Referring to FIG. 1, which is a schematic cross-sectional view of an electronic device 1 according to some embodiments of the present disclosure. In some embodiments, a substrate 10 is provided as shown in FIG. 1. In some embodiments, the substrate 10 may include glass, quartz, sapphire, ceramic, polyimide (PI), polycarbonate (PC), polyethylene terephthalate (PET), polypropylene (PP), other suitable materials, or a combination thereof, but the present disclosure is not limited thereto. In some embodiments, the substrate 10 may include a light-transmissive substrate, a semi-light-transmissive substrate, or an opaque substrate.

In some embodiments, a metal layer 20 may be formed on the substrate 10. In some embodiments, the metal layer 20 may be disposed between the substrate 10 and a subsequently formed buffer layer. In other words, before forming the buffer layer, the metal layer 20 may be formed on the substrate 10. In some embodiments, the metal layer 20 may include a conductive material. In some embodiments, the conductive material may include metal, metal nitride, semiconductor material, other suitable conductive materials, or a combination thereof, but the present disclosure is not limited thereto. In some embodiments, the conductive material may include gold (Au), nickel (Ni), platinum (Pt), palladium (Pd), iridium (Ir), titanium (Ti), chromium (Cr), tungsten (W), aluminum (Al), copper (Cu), molybdenum (Mo), silver (Ag), magnesium (Mg), alloys thereof, compounds thereof, or a combination thereof, but the present disclosure is not limited thereto. In some embodiments, the conductive material may include a transparent conductive oxide (TCO). For example, the transparent conductive oxide may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), other suitable transparent conductive materials, or a combination thereof, but the present disclosure is not limited thereto.

In some embodiments, the metal layer 20 may be formed by a deposition process, an etching process, a patterning process, other suitable processes, or a combination thereof. For example, the deposition process may include a chemical vapor deposition (CVD) process, a sputtering process, an evaporation process, a physical vapor deposition (PVD) process, other suitable deposition processes, or a combination thereof, but the present disclosure is not limited thereto. For example, the etching process may include a dry etching, a wet etching, other suitable etching processes, or a combination thereof, but the present disclosure is not limited thereto.

In some embodiments, the metal layer 20 may be a single layer (not shown) or may include multiple layers (as shown in FIG. 1). In some embodiments, the metal layer 20 may include a first metal layer 22 and a second metal layer 24. In some embodiments, in a normal direction of the substrate 10 (that is, the second direction D2), the first metal layer 22 may be disposed on the substrate 10, and the second metal layer 24 may be disposed on the first metal layer 22. In some embodiments, the first metal layer 22 may serve as an interface layer between the second metal layer 24 and the substrate 10. In some embodiments, the first metal layer 22 may include titanium and the second metal layer 24 may include copper. In some embodiments, the metal layer 20 may serve as a bottom gate electrode and/or a light-shielding layer in a double gate electrode in the electronic device 1. For example, the metal layer 20 may be used to electrically connect with a gate electrode formed subsequently to transmit gate signals. Alternatively, the metal layer 20 may be used to block the backlight and/or the light scattered within various components.

In some embodiments, as shown in FIG. 1, a buffer layer 30 may be formed on the substrate 10. In some embodiments, the buffer layer 30 may include an oxide such as silicon oxide, a nitride such as silicon nitride, an oxynitride such as silicon oxynitride, or other suitable buffer materials, or a combination thereof, but the present disclosure is not limited thereto. In some embodiments, the buffer layer 30 may be formed by the aforementioned deposition process, a thermal oxidation process, or other suitable processes.

In some embodiments, the buffer layer 30 may be a single layer (not shown) or may include multiple layers (as shown in FIG. 1). In some embodiments, the buffer layer 30 may include a first buffer layer 32 and a second buffer layer 34. In some embodiments, in the normal direction of the substrate 10 (that is, the second direction D2), the first buffer layer 32 may be disposed on the metal layer 20, and the second buffer layer 34 may be disposed on the first buffer layer 32. In some embodiments, the first buffer layer 32 may include silicon nitride and second buffer layer 34 may include silicon oxide. Accordingly, the second buffer layer 34 may prevent or reduce the diffusion of hydrogen (H) ions in the first buffer layer 32 into the subsequently formed semiconductor oxide layer. In detail, since the second buffer layer 34 is in contact with the subsequently formed semiconductor oxide layer, when the second buffer layer 34 includes silicon oxide, the second buffer layer 34 may avoid or reduce the diffusion of hydrogen ions generated from the precursors of silicon nitride into the subsequently formed semiconductor oxide layer. The second buffer layer 34 may prevent hydrogen ions from diffusing into the first part of the semiconductor oxide layer. If hydrogen ions diffuse into the first part of the semiconductor oxide layer, the conductivity of the first part of the semiconductor oxide layer will be too high, causing unnecessary conduction formed in the first part of the semiconductor oxide layer, thereby causing the transistor to deteriorate. Once the first part of the semiconductor oxide layer serving as the channel region forms unnecessary conduction, the gate electrode cannot control the switching of the transistor, thus causing the transistor to deteriorate.

In some embodiments, as shown in FIG. 1, a semiconductor oxide layer 40 may be formed on the buffer layer 30. In some embodiments, the semiconductor oxide layer 40 may include a transparent conductive oxide. In some embodiments, the semiconductor oxide layer 40 may include indium, gallium, zinc, or a combination thereof, but the present disclosure is not limited thereto. For example, the semiconductor oxide layer 40 may include indium and gallium. In some embodiments, the semiconductor oxide layer 40 may include indium gallium oxide (IGO) or indium gallium zinc oxide (IGZO). In some embodiments, the semiconductor oxide layer 40 may be disposed between the metal layer 20 and a subsequently formed gate electrode.

In some embodiments, as shown in FIG. 1, the semiconductor oxide layer 40 may have a first part 40A and a second part 40B adjacent to the first part 40A. In some embodiments, the first part 40A may be disposed between the second parts 40B along the first direction D1. In some embodiments, along the normal direction of the substrate 10, the first part 40A of the semiconductor oxide layer 40 may correspond to a subsequently formed gate electrode. In some embodiments, the projection range of the gate electrode on the semiconductor oxide layer 40 is the range of the first part 40A. In other words, the portion of the semiconductor oxide layer 40 on which the gate electrode is disposed may be referred to as the first part 40A, and the remaining portion of the semiconductor oxide layer 40 on which the gate electrode is not disposed may be referred to as the second part 40B. In some embodiments, the first part 40A of the semiconductor oxide layer 40 may serve as a channel region of the electronic device 1, and the second part 40B of the semiconductor oxide layer 40 may serve as a conductive region of the electronic device 1. In some embodiments, the second part 40B may be an N⁺ region doped with N-type dopants to electrically connect the semiconductor oxide layer 40 to other components, but the present disclosure is not limited thereto.

In some embodiments, as shown in FIG. 1, a first insulating layer 50 may be formed on the semiconductor oxide layer 40. In other words, before forming the subsequent gate electrode, the first insulating layer 50 is formed on the semiconductor oxide layer 40. In some embodiments, the first insulating layer 50 may include an oxide such as silicon oxide, a nitride such as silicon nitride, an oxynitride such as silicon oxynitride, other suitable insulating materials, or a combination thereof, but the present disclosure is not limited thereto. In some embodiments, the first insulating layer 50 may serve as a gate insulating layer.

In some embodiments, as shown in FIG. 1, a gate electrode 60 may be formed on the first insulating layer 50. For example, the gate electrode 60 may be disposed on the buffer layer 30. In some embodiments, the materials and formation methods of the gate electrode 60 may be the same as or different from the materials and formation methods of the metal layer 20. In some embodiments, the gate electrode 60 may include a first conductive layer 62 and a second conductive layer 64. In some embodiments, the first conductive layer 62 may be disposed on the first insulating layer 50, and the second conductive layer 64 may be disposed on the first conductive layer 62. In some embodiments, the first conductive layer 62 may include titanium and the second conductive layer 64 may include copper. In some embodiments, the first conductive layer 62 may serve as an interface layer between the second conductive layer 64 and the first insulating layer 50. In some embodiments, in the normal direction of the substrate 10, the gate electrode 60 may overlap the first part 40A of the semiconductor oxide layer 40 and the gate electrode 60 may not overlap the second part 40B of the semiconductor oxide layer 40. In some embodiments, in a cross-sectional view, the width of the first insulating layer 50 is greater than the width of the gate electrode 60. However, in some embodiments, in a cross-sectional view, the width of the first insulating layer 50 is substantially equal to the width of the gate electrode 60.

In some embodiments, as shown in FIG. 1, a second insulating layer 70 may be formed on the buffer layer 30, the semiconductor oxide layer 40, the first insulating layer 50, and the gate electrode 60. In some embodiments, the material and formation method of the second insulating layer 70 may be the same as or different from the materials and formation method of the first insulating layer 50. In some embodiments, the second insulating layer 70 may serve as an interlayer dielectric (ILD) layer. In some embodiments, the second insulating layer 70 may include silicon oxynitride.

In some embodiments, before forming the second insulating layer 70, a surface treatment process, such as a plasma bombardment process, may be performed on a top surface of the semiconductor oxide layer 40 by using hydrogen (H), so as to enhance the conductivity of the second part 40B of the semiconductor oxide layer 40. Then, the second insulating layer 70 is formed on the semiconductor oxide layer 40, and hydrogen ions on the top surface of the semiconductor oxide layer 40 may partially diffuse into the second insulating layer 70. It should be noted that since the surface treatment process is performed on the top surface of the semiconductor oxide layer 40 and the first part 40A of the semiconductor oxide layer 40 is blocked by the gate electrode 60, the diffusion of hydrogen ions into the first part 40A of the semiconductor oxide layer 40 may be avoided. If the hydrogen ions diffuse into the first part 40A of the semiconductor oxide layer 40, the conductivity of the first part 40A of the semiconductor oxide layer 40 will be too high, causing unnecessary conduction formed in the first part 40A of the semiconductor oxide layer 40.

In other embodiments, during the process of forming the second insulating layer 70 on the semiconductor oxide layer 40, by increasing the concentration of hydrogen ions in the atmosphere, for example, increasing the concentration of hydrogen ions in the process chamber, hydrogen ions in the atmosphere enter the semiconductor oxide layer 40 and the second insulating layer 70, so as to improve the conductivity of the semiconductor oxide layer 40. In some embodiments, the surface treatment process may be performed, and then the ion implantation process described below may be performed. In other embodiments, the ion implantation process described below may be performed, and then the surface treatment process may be performed.

In some embodiments, as shown in FIG. 1, a passivation layer 80 may be formed on the second insulating layer 70. In some embodiments, the material and formation method of the passivation layer 80 may be the same as or different from the material and formation method of the first insulating layer 50. In some embodiments, the passivation layer 80 may include silicon nitride.

In some embodiments, as shown in FIG. 1, an ion implantation process IPB may be performed on the semiconductor oxide layer 40 by using boron (B). In some embodiments, after the gate electrode 60 is formed, and after the second insulating layer 70 is formed on the buffer layer 30, the semiconductor oxide layer 40, the first insulating layer 50, and the gate electrode 60, the ion implantation process IPB may be performed on the semiconductor oxide layer 40. Since the ion implantation process IPB is blocked by the gate electrode 60, boron ions are implanted into the second part 40B of the semiconductor oxide layer 40 and are not substantially implanted into the first part 40A of the semiconductor oxide layer 40.

When the ion implantation process IPB is performed on the semiconductor oxide layer 40 by using boron, the boron ions will impact the oxygen atoms in the semiconductor oxide layer 40, causing oxygen vacancies generated in the semiconductor oxide layer 40. That is, free electrons are generated. Thus, the conductivity of the second part 40B of the semiconductor oxide layer 40 may be increased. Therefore, the second part 40B of the semiconductor oxide layer 40 may be a conductive region, so that the semiconductor oxide layer 40 may be electrically connected to other components by the second part 40B of the semiconductor oxide layer 40. Compared with using other ions such as hydrogen ions to perform the ion implantation process, the parameters of the boron ion implantation process may be accurately adjusted, in order to avoid hydrogen ions from diffusing into the channel region of the electronic device 1. If hydrogen ions diffuse into the channel region of the electronic device 1, the unnecessary conduction will be formed in the channel region of the electronic device 1. Accordingly, using the boron ion implantation process may improve the controllability of the manufacturing method of the electronic device 1 and/or improve the reliability of the electronic device 1.

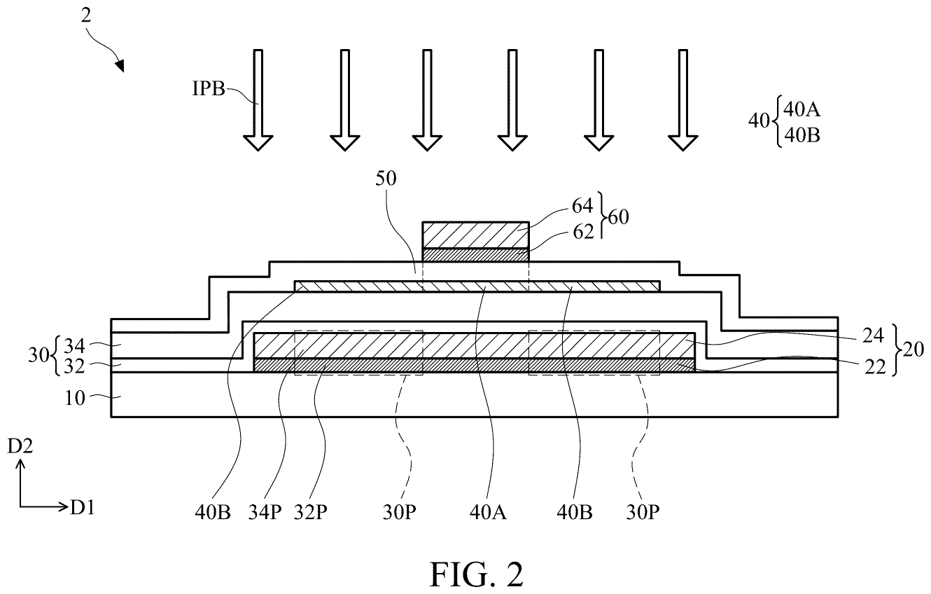

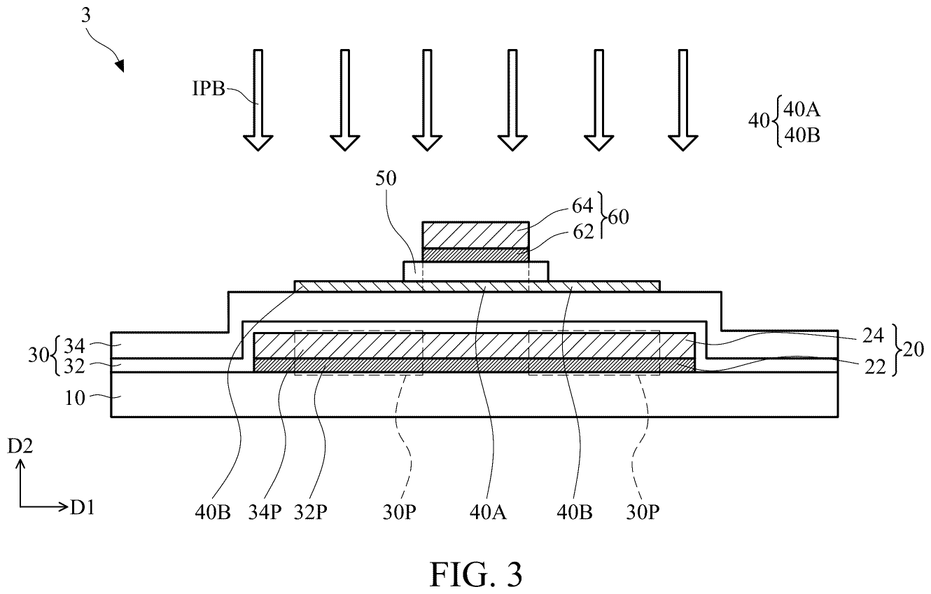

It should be noted that the process sequence for performing the ion implantation process IPB is not limited thereto and may be as shown in the following FIGS. 2 and 3.

In the following, the same or similar reference numerals and descriptions are omitted.

Referring to FIG. 2, which is a schematic cross-sectional view of an electronic device 2 according to some embodiments of the present disclosure. In some embodiments, as shown in FIG. 2, after the first insulating layer 50 is conformally formed on the buffer layer 30 and the semiconductor oxide layer 40, the gate electrode 60 is formed on the first insulating layer 50. Then, after the gate electrode 60 is formed, the ion implantation process IPB is performed on the semiconductor oxide layer 40. In this embodiment, a patterning process is optionally performed to pattern the first insulating layer 50. Then, the second insulating layer 70 and the passivation layer 80 may be further formed.

Referring to FIG. 3, which is a schematic cross-sectional view of an electronic device 3 according to some embodiments of the present disclosure. In some embodiments, as shown in FIG. 3, after the first insulating layer 50 is conformally formed on the buffer layer 30 and the semiconductor oxide layer 40, the gate electrode 60 is formed on the first insulating layer 50. Then, a patterning process is performed to pattern the first insulating layer 50 to expose the top surface of the second part 40B of the semiconductor oxide layer 40. Furthermore, after patterning the first insulating layer 50, the ion implantation process IPB is performed on the semiconductor oxide layer 40. In other embodiments, as shown in FIG. 3, after the first insulating layer 50 is conformally formed on the buffer layer 30 and the semiconductor oxide layer 40, a patterning process is performed to pattern the first insulating layer 50 to expose the top surface of the second part 40B of the semiconductor oxide layer 40. Then, the gate electrode 60 is formed on the patterned first insulating layer 50. Furthermore, the ion implantation process IPB is performed on the semiconductor oxide layer 40.

In the following, the electronic device 1 may be used as an example to illustrate the results of elemental analysis after performing the ion implantation process IPB, but the present disclosure is not limited thereto.

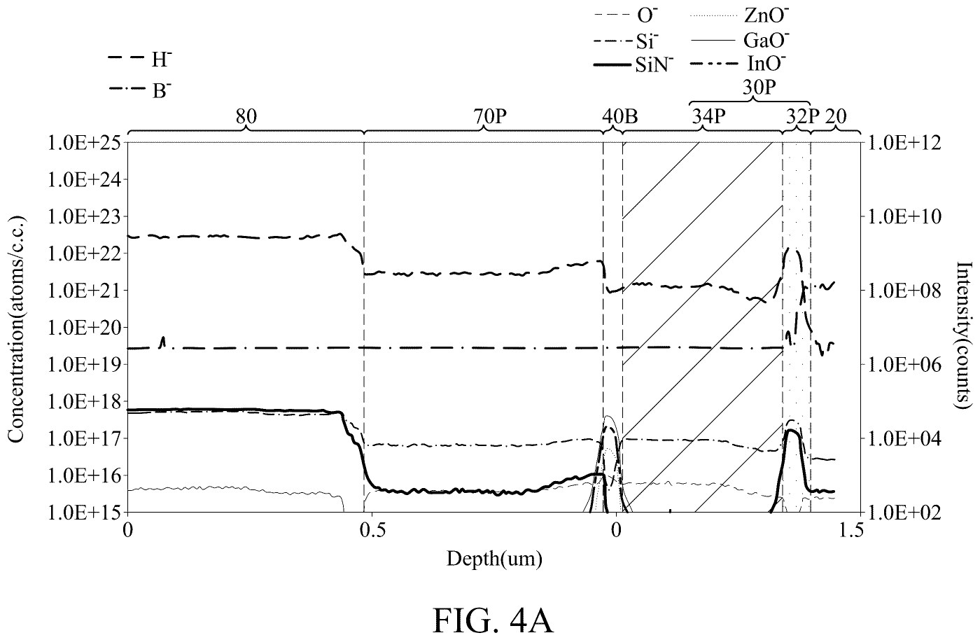

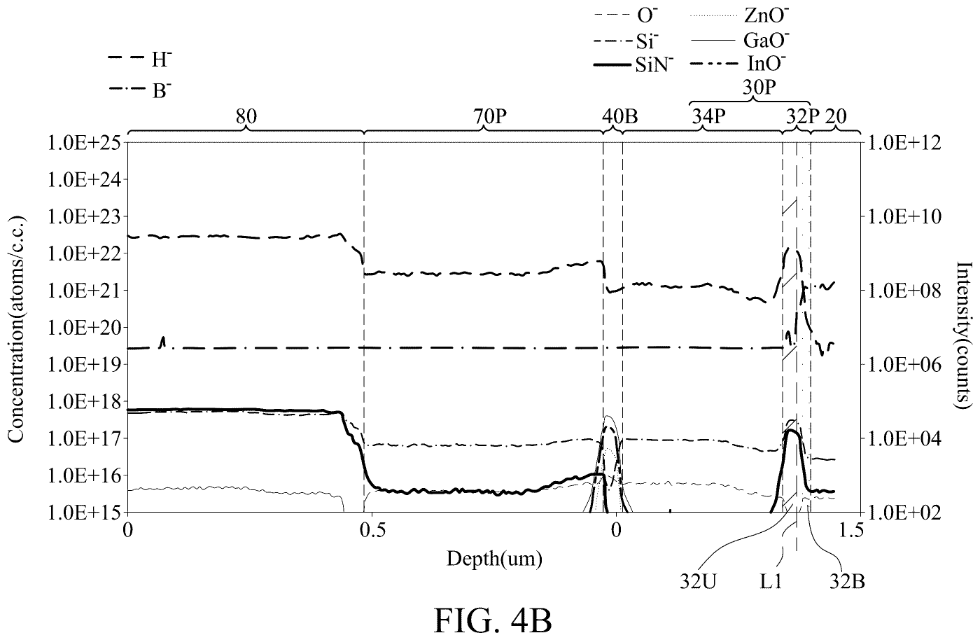

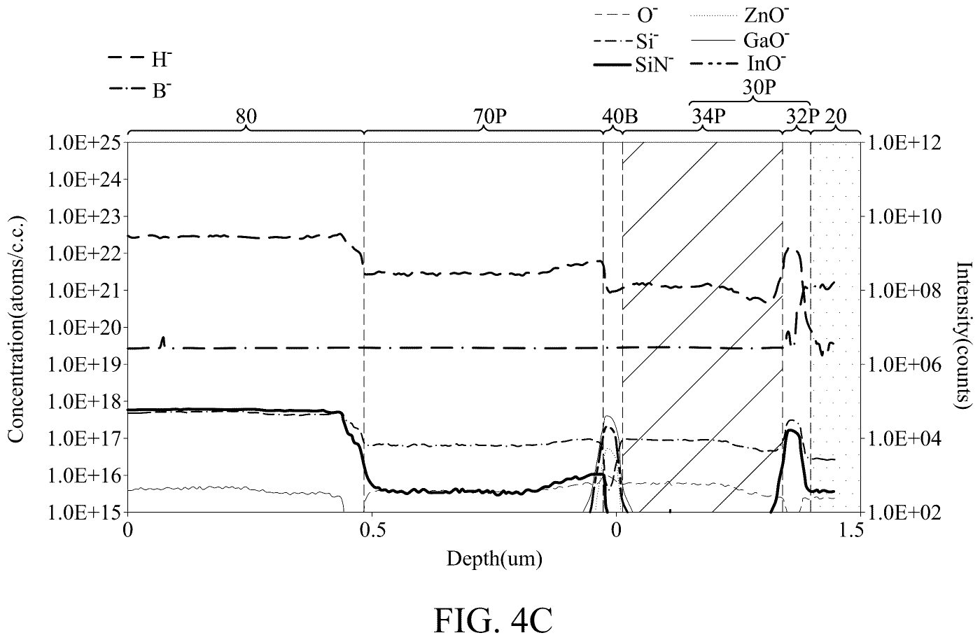

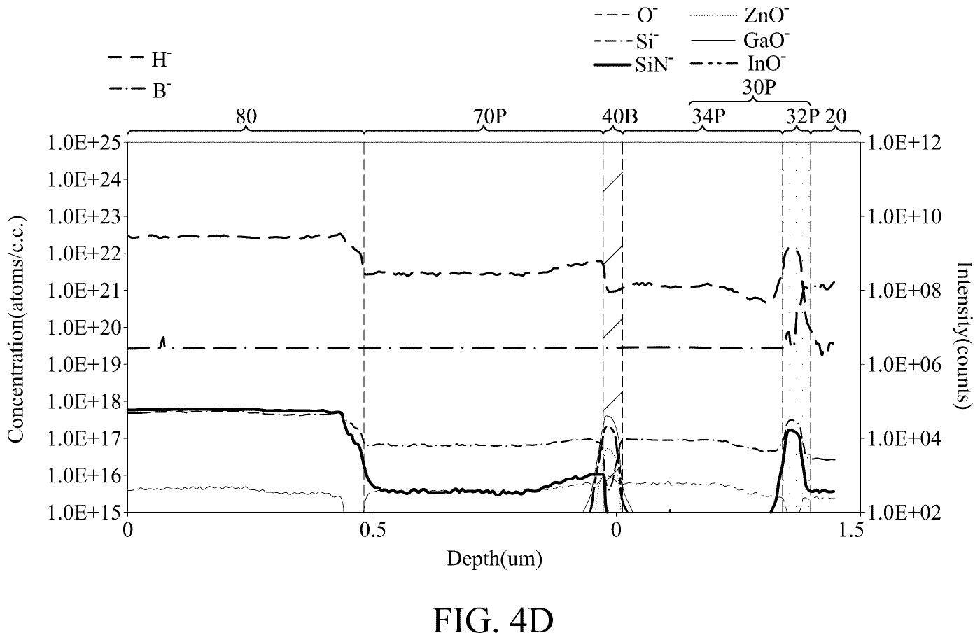

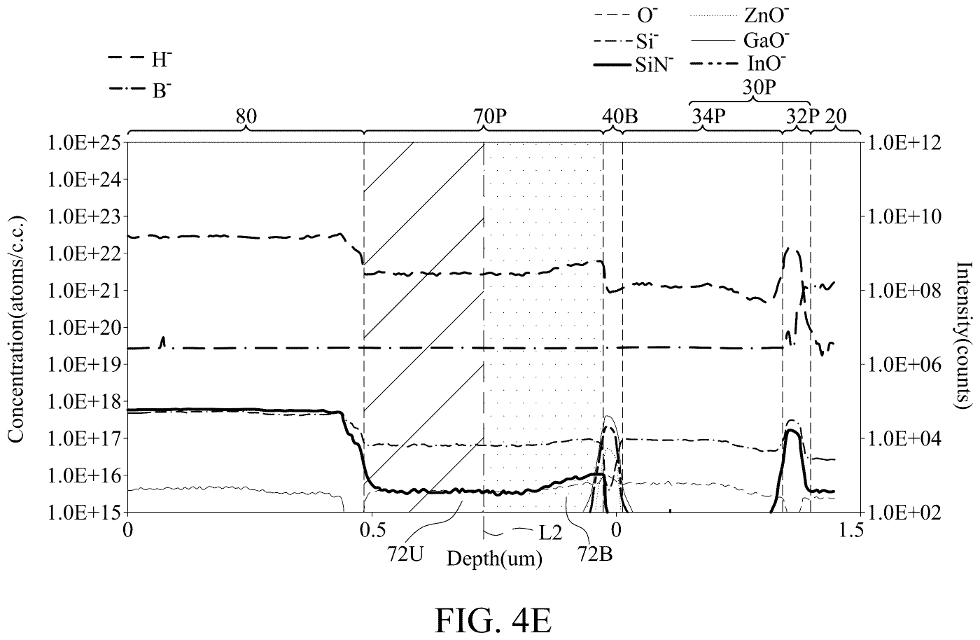

For ease of explanation, in the following, different components are marked (for example, marked with slashes and dots) in FIGS. 4A to 4E respectively, but FIGS. 4A to 4E substantially represent the same analysis results.

Referring to FIGS. 4A to 4E, which are respectively schematic diagrams of elemental analysis of the electronic device 1 according to some embodiments of the present disclosure. FIGS. 4A to 4E respectively show schematic diagrams of elemental analysis performed by TOF-SIMS analysis in negative ion mode along the cross-section A-A of the electronic device 1 shown in FIG. 1. The minimum analyzable value of the concentration analyzed by TOF-SIMS in negative ion mode is in the range of 1.0 E+19 atoms/c.c. to 1.0 E+20 atoms/c.c., wherein, the concentrations of hydrogen (H⁻) ions and boron (B⁻) ions refer to the vertical axis coordinate on the left side (concentration (atoms/cubic centimeter (atoms/c.c.))), and their concentrations are the concentrations after quantitative analysis. The contents of O⁻, Si⁻, SiN⁻, ZnO⁻, GaO⁻, and InO⁻ refer to the vertical axis coordinate on the right side (intensity (counts)), and their intensities are the counts after qualitative analysis. In some embodiments, the concentration of boron negative (B⁻) ions analyzed by TOF-SIMS in negative ion mode is equivalent to the concentration of boron.

Referring to FIG. 1 and FIG. 4A together. In some embodiments, as shown in FIG. 1, in the normal direction of the substrate 10, a part 30P of the buffer layer 30 may overlap the second part 40B of the semiconductor oxide layer 40. In some embodiments, in the normal direction of the substrate 10, the part 30P of the buffer layer 30 may have a first portion 32P and a second portion 34P disposed on the first portion 32P. In some embodiments, when the buffer layer 30 includes multiple layers, for example, when the buffer layer 30 includes a composite material, the first and second portions of the buffer layer 30 are distinguished by different types of materials. In some embodiments, as shown in FIG. 1, the buffer layer 30 includes a first buffer layer 32 and a second buffer layer 34, so the first portion 32P of the part 30P of the buffer layer 30 may be a portion of the first buffer layer 32, and the second portion 34P of the part 30P of the buffer layer 30 may be a portion of the second buffer layer 34. In other embodiments, when the buffer layer 30 is a single layer (not shown), the first and second portions of the buffer layer 30 may be distinguished by a half of the thickness of the buffer layer 30 in the normal direction of the substrate 10.

In some embodiments, as shown in FIGS. 1 and 4A, compared to the concentration of boron in a portion of the buffer layer 30 adjacent to semiconductor oxide layer 40, the concentration of boron in another portion of buffer layer 30 away from semiconductor oxide layer 40 is higher. In some embodiments, after performing the ion implantation process IPB, the concentration of boron in the first portion 32P (marked with dots) of the part 30P of the buffer layer 30 is greater than that in the second portion 34P (marked with slashes) of the part 30P of the buffer layer 30. Accordingly, by adjusting the parameters for performing the ion implantation process IPB, it may be avoided that, for example, during the subsequent thermal process of the semiconductor oxide layer 40, boron ions are diffused into the first part 40A of the semiconductor oxide layer 40, causing unnecessary conduction formed in the first part 40A of the semiconductor oxide layer 40.

For example, parameters for performing the ion implantation process IPB may be adjusted by increasing the doping energy and/or increasing the doping depth of the ion implantation process IPB, so that the doped boron ions are further away from the semiconductor oxide layer 40. Therefore, the ion implantation process IPB may improve the problem that the first part 40A of the semiconductor oxide layer 40 serving as the channel region produces unnecessary conduction and cannot control the switching of the transistor through the gate electrode, thereby degrading the transistor. Furthermore, since the doping energy of the ion implantation process IPB may be higher, more oxygen vacancies may be formed in the semiconductor oxide layer 40 to improve the conductivity of the semiconductor oxide layer 40.

In some embodiments, as shown in FIGS. 1 and 4B, compared to the concentration of boron in a portion of the first portion 32P of the buffer layer 30 adjacent to semiconductor oxide layer 40, the concentration of boron in another portion of the first portion 32P of buffer layer 30 away from semiconductor oxide layer 40 is higher. In some embodiments, a first line L1 is a virtual extension line representing half the thickness of the first portion 32P in the normal direction of the substrate 10, so that the first portion 32P is divided into a lower portion 32B and an upper portion 32U disposed on the lower portion 32B by the first line L1. In some embodiments, after performing the ion implantation process IPB, the concentration of boron in the lower portion 32B (marked with dots) is greater than the concentration of boron in the upper portion 32U (marked with slashes). Accordingly, it is possible to prevent boron ions from diffusing into the semiconductor oxide layer 40 and forming unnecessary conduction in the first part 40A of the semiconductor oxide layer 40.

In some embodiments, as shown in FIGS. 1 and 4C, after performing the ion implantation process IPB, the metal layer 20 (marked with dots) includes boron. Accordingly, boron may be used to protect the metal layer 20 from oxidation. For example, when the metal layer 20 includes copper, boron may serve as a deoxidizer (or antioxidant) to reduce the possibility that the copper will be oxidized to degrade the conductivity of the metal layer 20. In some embodiments, as shown in FIGS. 1 and 4C, after performing the ion implantation process IPB, the concentration of boron in the metal layer 20 (marked by dots) is greater than the concentration of boron in the second portion 34P (marked with slashes) of the part 30P of the buffer layer 30. Accordingly, it is possible to prevent boron ions from diffusing into the semiconductor oxide layer 40 and forming unnecessary conduction in the first part 40A of the semiconductor oxide layer 40.

In some embodiments, as shown in FIGS. 1 and 4D, after performing the ion implantation process IPB, the concentration of boron in the second part 40B (marked with slashes) of the semiconductor oxide layer 40 is less than the concentration of boron in the first portion 32P (marked with dots) of the part 30P of the buffer layer 30. Accordingly, by controlling the parameters for performing the ion implantation process IPB, boron ions are prevented from affecting the properties of the semiconductor oxide layer 40. Therefore, it is possible to prevent boron ions from diffusing into the semiconductor oxide layer 40 and forming unnecessary conduction in the first part 40A of the semiconductor oxide layer 40.

Referring to FIGS. 1 and 4E. In some embodiments, as shown in FIG. 1, in the normal direction of the substrate 10, the part 70P of the second insulating layer 70 may overlap the second part 40B of the semiconductor oxide layer 40. In some embodiments, in the normal direction of the substrate 10, the part 70P of the second insulating layer 70 may have a first portion and a second portion disposed on the first portion. In some embodiments, when the second insulating layer 70 includes multiple layers (not shown), for example, when the second insulating layer 70 includes a composite material, the first and the second portions of the second insulating layer 70 are distinguished by different types of materials. In other embodiments, as shown in FIG. 1, when the second insulating layer 70 is a single layer, the first portion 72B of the second insulating layer 70 and second portion 72U disposed on the first portion 72B may be distinguished by a half of the thickness of the second insulating layer 70 in the normal direction of the substrate 10. In some embodiments, a second line L2 is a virtual extension line representing half the thickness of the second insulating layer 70 in the normal direction of the substrate 10, so that the second insulating layer 70 is divided into the first portion 72B and the second portion 72U by the second line L2. In some embodiments, as shown in FIGS. 1 and 4E, compared with the concentration of hydrogen in a portion of the second insulating layer 70 adjacent to the semiconductor oxide layer 40, the concentration of hydrogen in another portion of the second insulating layer 70 away from the semiconductor oxide layer 40 is lower. In some embodiments, after performing the ion implantation process IPB, the concentration of hydrogen in the first portion 72B (marked with dots) of the part 70P of the second insulating layer 70 is greater than the concentration of hydrogen in the second portion 72U (marked with slashes) of the part 70P of the second insulating layer 70. Accordingly, by performing the surface treatment process on the top surface of the semiconductor oxide layer 40 using hydrogen, the conductivity of the second part 40B of the semiconductor oxide layer 40 may be improved.

In some embodiments, the concentration of hydrogen in the first portion 72B of the part 70P of the second insulating layer 70 may be in a ranges of 1.0 E+20 atoms/cubic centimeter to 1.0 E+23 atoms/cubic centimeter. For example, the concentration of hydrogen in the first portion 72B of the part 70P of the second insulating layer 70 may be in a range of 1.0 E+21 atoms/cubic centimeter to 1.0 E+22 atoms/cubic centimeter. For example, the concentration of hydrogen in the first portion 72B of the part 70P of the second insulating layer 70 may be 1.0 E+21 atoms/cubic centimeter, 2.0 E+21 atoms/cubic centimeter, 3.0 E+21 atoms/cubic centimeter, 4.0 E+21 atoms/cubic centimeter, 5.0 E+21 atoms/cubic centimeter, 6.0 E+21 atoms/cubic centimeter, 7.0 E+21 atoms/cubic centimeter, 8.0 E+21 atoms/cubic centimeter, 9.0 E+21 atoms/cubic centimeter, 1.0 E+22 atoms/cubic centimeter, or any value or any range of values between the aforementioned values, but the present disclosure is not limited thereto. In other embodiments, in the normal direction of the substrate 10, the thickness of the part 70P of the second insulating layer 70 is evenly divided into three portions. Therefore, the part 70P of the second insulating layer 70 may include a lower portion, a middle portion, and an upper portion, wherein the middle portion is disposed on the lower portion, and the upper portion is disposed on the middle portion. In some embodiments, the concentration of boron in the lower portion of the part 70P of the second insulating layer 70 is greater than the concentrations of boron in the middle portion and the upper portion of the part 70P of the second insulating layer 70.

It should be noted that, as shown in FIGS. 4A to 4E, a curve of the concentration of boron in the second portion 34P of the part 30P of the buffer layer 30, the semiconductor oxide layer 40, the second insulating layer 70, and the passivation layer 80 is similar to a horizontal line, it is shows that boron may be included in the second portion 34P of the part 30P of the buffer layer 30, the semiconductor oxide layer 40, the second insulating layer 70, and the passivation layer 80, but the concentration of boron may be lower than the minimum analyzable value of the concentration analyzed by TOF-SIMS analysis in negative ion mode. Therefore, TOF-SIMS analysis in positive ion mode will be used for explanation hereafter. In some embodiments, the concentration of boron cations (B⁺) ions analyzed by TOF-SIMS in positive ion mode is equivalent to the concentration of boron (for example, the concentrations may be substantially equal).

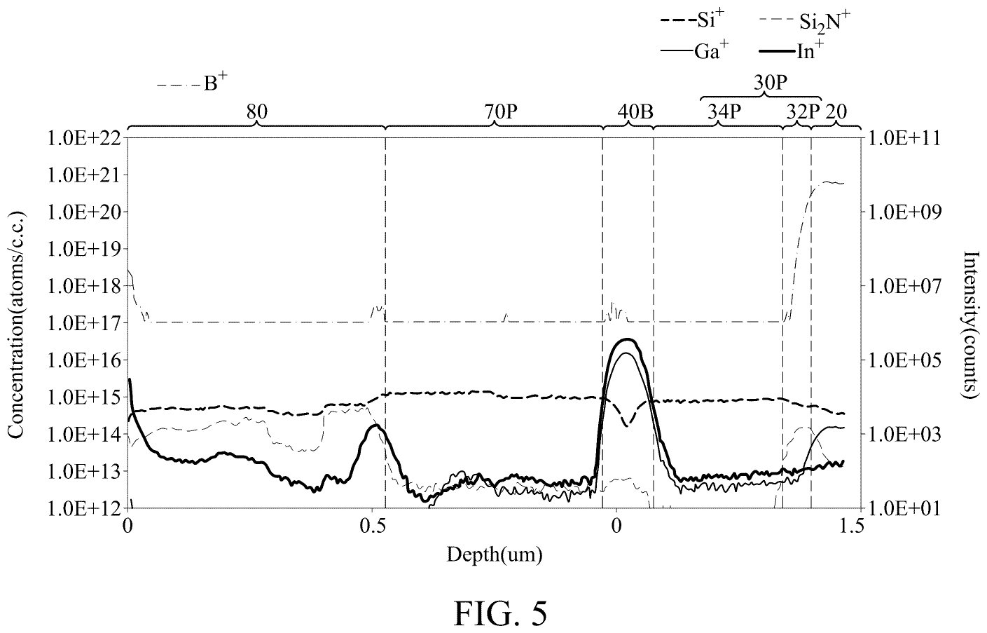

Referring to FIG. 5, which is a schematic diagram of elemental analysis of the electronic device 1 according to some embodiments of the present disclosure. FIG. 5 shows a schematic diagram of elemental analysis performed by TOF-SIMS analysis in the positive ion mode along the cross-section A-A of the electronic device 1 shown in FIG. 1. The minimum analyzable value of the concentration analyzed by TOF-SIMS in positive ion mode is about 1.0 E+17 atoms/cubic centimeter (atoms/c.c.). The concentration of boron (B⁺) ions refers to the vertical axis coordinate on the left side (concentration (atoms/cubic centimeter (atoms/c.c.))), and its concentration is the concentrations after quantitative analysis. The contents of Si⁺, Ga⁺, Si₂N⁺, and In⁺ refer to the vertical axis coordinate on the right side (intensity (counts)), and their intensities are counts after qualitative analysis. In some embodiments, the positive ion mode may show concentration more sensitively because the minimum analyzable value of the positive ion mode is lower than the minimum analyzable value of the negative ion mode.

In some embodiments, as shown in FIG. 5, the concentration of boron in the second part 40B of the semiconductor oxide layer 40 may be in a range of 1.0 E+17 atoms/cubic centimeter (atoms/c.c) to 1.0 E+18 atoms/cubic centimeter. For example, the concentration of boron in the second part 40B of the semiconductor oxide layer 40 may be 1.0 E+17 atoms/cubic centimeter, 2.0 E+17 atoms/cubic centimeter, 3.0 E+17 atoms/cubic centimeter, 4.0 E+17 atoms/cubic centimeter, 5.0 E+17 atoms/cubic centimeter, 6.0 E+17 atoms/cubic centimeter, 7.0 E+17 atoms/cubic centimeter, 8.0 E+17 atoms/cubic centimeter, 9.0 E+17 atoms/cubic centimeter, 1.0 E+18 atoms/cubic centimeter, or any value or any range of values between the aforementioned values, but the present disclosure is not limited thereto. In some embodiments, after performing the ion implantation process IPB, the concentration of boron in the second part 40B of the semiconductor oxide layer 40 is less than the concentration of boron in the first portion 32P of the part 30P of the buffer layer 30. Accordingly, by controlling the parameters for performing the ion implantation process IPB, boron ions are prevented from affecting the properties of the semiconductor oxide layer 40.

In some embodiments, as shown in FIG. 5, the concentration of boron in the first portion 32P of the part 30P of the buffer layer 30 may be in a range of 1.0 E+17 atoms/cubic centimeter to 1.0 E+21 atoms/cubic centimeter. For example, the concentration of boron in the first portion 32P of the part 30P of the buffer layer 30 may be 1.0 E+17 atoms/cubic centimeter, 5.0 E+17 atoms/cubic centimeter, 1.0 E+18 atoms/cubic centimeter, 5.0 E+18 atoms/cubic centimeter, 1.0 E+19 atoms/cubic centimeter, 5.0 E+19 atoms/cubic centimeter, 1.0 E+20 atoms/cubic centimeter, 5.0 E+20 atoms/cubic centimeter, 1.0 E+21 atoms/cubic centimeter, or any value or any range of values between the aforementioned values, but the present disclosure is not limited thereto. Accordingly, it is possible to prevent boron ions from diffusing into the semiconductor oxide layer 40 and forming unnecessary conduction in the first part 40A of the semiconductor oxide layer 40.

In some embodiments, the electronic devices 1 to 3 of the present disclosure may be display devices, and the display devices may include dual gate electrode transistors. Accordingly, the semiconductor oxide layer may provide high carrier mobility to improve the properties of the electronic devices 1 to 3.

In summary, according to embodiments of the present disclosure, an electronic device and a manufacturing method thereof are provided, which may adjust the parameters of the ion implantation process, such as doping energy, doping depth, doping concentration, dopant type, and the like, to form a buffer layer, thereby improving the properties of electronic devices. For example, the present disclosure may improve the conductivity of electronic devices, prevent thermal diffusion from affecting other components, and/or prevent electrode degradation.

The features among the various embodiments may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device, comprising:
a substrate;
a buffer layer disposed on the substrate;
an oxide semiconductor layer disposed on the buffer layer, having a first part and a second part adjacent to the first part; and
a gate electrode overlapping the first part;
wherein a part of the buffer layer is overlapped with the second part of the oxide semiconductor layer, the part of the buffer layer has a first portion and a second portion disposed on the first portion, and a concentration of boron in the first portion is greater than a concentration of boron in the second portion.

2. The electronic device according to claim 1, wherein the first portion has a lower portion and an upper portion disposed on the lower portion, wherein a concentration of boron in the lower portion is greater than a concentration of boron in the upper portion.

3. The electronic device according to claim 1, further comprising a metal layer disposed between the substrate and the buffer layer, wherein the metal layer comprises boron.

4. The electronic device according to claim 3, wherein a concentration of boron in the metal layer is greater than the concentration of boron in the second portion of the buffer layer.

5. The electronic device according to claim 1, wherein a concentration of boron in the second part of the oxide semiconductor layer is less than the concentration of boron in the first portion of the buffer layer.

6. The electronic device according to claim 5, wherein the concentration of boron in the second part of the oxide semiconductor layer is in a range from 1.0 E+17 to 1.0 E+18 atoms/c.c..

7. The electronic device according to claim 1, further comprising an insulating layer disposed on the oxide semiconductor layer, wherein a part of the insulating layer is overlapped with the second part of the oxide semiconductor layer, the part of the insulating layer has a first portion and a second portion disposed on the first portion, and a concentration of hydrogen in the first portion of the insulating layer is greater than a concentration of hydrogen in the second portion of the insulating layer.

8. The electronic device according to claim 7, wherein the concentration of hydrogen in the first portion is in a range from 1.0 E+20 to 1.0 E+23 atoms/c.c..

9. The electronic device according to claim 1, wherein the concentration of boron in the first portion of the buffer layer is in a range from 1.0 E+17 atoms/c.c. to 1.0 E+21 atoms/c.c..

10. The electronic device according to claim 1, wherein the oxide semiconductor layer is disposed between a metal layer and the gate electrode.

11. The electronic device according to claim 1, wherein the oxide semiconductor layer comprises indium and gallium.

12. The electronic device according to claim 1, which is a display device.

13. A method of manufacturing an electronic device, comprising:
providing a substrate;
forming a buffer layer on the substrate;
forming an oxide semiconductor layer on the buffer layer, the oxide semiconductor layer has a first part and a second part;
forming a gate electrode on the buffer layer, wherein the gate electrode overlaps the first part; and
performing an ion implantation process by boron on the oxide semiconductor layer;
wherein a part of the buffer layer is overlapped with the second part of the oxide semiconductor layer, the part of the buffer layer has a first portion and a second portion disposed on the first portion, and after the ion implantation process, a concentration of boron in the first portion is greater than a concentration of boron in the second portion.

14. The method according to claim 13, wherein performing the ion implantation process is after forming the gate electrode.

15. The method according to claim 14, before forming the gate electrode, further comprising forming a first insulating layer on the oxide semiconductor layer.

16. The method according to claim 15, before performing the ion implantation process, further comprising patterning the first insulating layer to expose the second part of the oxide semiconductor layer.

17. The method according to claim 13, after forming the gate electrode, further comprising forming a second insulating layer on the gate electrode, wherein performing the ion implantation process is after forming the second insulating layer.

18. The method according to claim 13, before forming the buffer layer, further comprising forming a metal layer on the substrate.

19. The method according to claim 18, after performing the ion implantation process, wherein the metal layer comprises boron.

20. The method according to claim 13, wherein the oxide semiconductor layer comprises indium and gallium.
